(19) United States
(12) Patent Application Publication
(10) Pub. No.: US 2009/0325323 A1
(43) Pub. Date: Dec. 31, 2009

(54) AQUEOUS DISPERSION FOR CHEMICAL MECHANICAL POLISHING, PRODUCTION METHOD THEREOF, AND CHEMICAL MECHANICAL POLISHING METHOD

(75) Inventors: Tomikazu Ueno, Tokyo (JP); Norihiko Ikeda, Tokyo (JP); Mitsuru Meno, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: JSR CORPORATION, Chuo-ku (JP)

(21) Appl. No.: 12/373,897

(22) PCT Filed: Jul. 11, 2007
(86) PCT No.: PCT/JP07/64124

§ 371 Date: Jan. 15, 2009

(30) Foreign Application Priority Data
Jul. 18, 2006 (JP) 2006-195571

(51) Int. Cl. C09G 1/02; H01L 21/304; C09K 13/00

(52) U.S. Cl. 438/10; 438/693; 252/79.1; 257/E21.23

(57) ABSTRACT

There is provided an aqueous dispersion for chemical mechanical polishing that comprises abrasives comprising:
(A) 100 parts by weight of inorganic particles comprising ceria,
(B) 5 to 100 parts by weight of cationic organic polymer particles, and
(C) 5 to 120 parts by weight of anionic water-soluble compound.

The aqueous dispersion for chemical mechanical polishing is preferably produced by a method comprising a step of adding a second liquid comprising (C) 5 to 30 wt % of anionic water-soluble compound to a first liquid comprising (A) 0.1 to 10 wt % of inorganic particles comprising ceria and (B) 5 to 100 parts by weight of cationic organic polymer particles based on 100 parts by weight of the inorganic particles (A).

### FILED OF THE INVENTION

The present invention relates to an aqueous dispersion for chemical mechanical polishing, a method for producing the aqueous dispersion, and a chemical mechanical polishing method. More specifically, the present invention relates to an aqueous dispersion for chemical mechanical polishing that is especially useful for chemical mechanical polishing of an insulation film in a production process of a semiconductor device, a method for producing the aqueous dispersion, and a chemical mechanical polishing method using the aqueous dispersion.

### BACKGROUND ART

Along with an improvement in the integration, multilayer wiring and the like of semiconductor device, the storage capacity of a memory device has been increasing dramatically. This is backed by advancement of microfabrication technique. However, despite the multilayer wiring or the like, the size of chips has been increasing and the number of steps has been increasing along with an improvement in finer design rule, causing an increase in the costs of chips. Under such circumstances, a chemical mechanical polishing technique has been introduced for polishing of a processed film or the like and widely used. By application of this chemical mechanical polishing technique, many finer design techniques including planarization have been embodied.

As such a finer design technique, shallow trench isolation, a so-called STI technique, is known, for example. In this STI technique, chemical mechanical polishing is conducted to remove an excess insulating layer formed on a wafer substrate. In this chemical mechanical polishing step, flatness of polished surface is important, and various polishing agents have been studied accordingly.

For example, Japanese Patent Application Laid-Open Nos. 326469/1993 and 270402/1997 disclose that use of an aqueous dispersion using ceria as abrasives in the chemical mechanical polishing step of the STI results in a polished surface having a relatively small number of polishing scratches at a high removal rate.

In recent years, along with further increases in multilayering and definition of semiconductor devices, further improvements in yield and throughput of the semiconductor devices have been increasingly demanded. Along with that, high-speed polishing which ensures that a polished surface after the chemical mechanical polishing step has substantially no polishing scratches been increasingly demanded.

It has been reported that for reduction of polishing scratches on a polished surface, a surfactant such as a chitosan acetate, dodecylamine or polyvinyl pyrrolidone is effective (for example, Japanese Patent Application Laid-Open Nos. 109809/2000, 7061/2001 and 185514/2001). However, although these techniques are effective for reduction of polishing scratches, the removal rate is decreased, and an improvement in throughput has not yet been achieved.

The present applicant has proposed an aqueous dispersion for chemical mechanical polishing that achieves the above object and contains ceria-containing abrasives in a concentration of not higher than 1.5 wt %, the abrasives having an average particle diameter of not smaller than 1.0 μm (Japanese Patent Application Laid-Open No. 32611/2006). This aqueous dispersion significantly reduces generation of scratches on a polished surface in chemical mechanical polishing of an insulation film in particular and shows an improved removal rate. However, one skilled in the art desires higher removal rate.

Meanwhile, in such a chemical mechanical polishing step as described above, ending the polishing step immediately after an excess portion on a surface to be polished is removed by polishing is an important factor which contributes to savings of semiconductor material, aqueous dispersion for chemical mechanical polishing and the like and an improvement in throughput of products. A polishing end point has been determined based on empirically acquired time. However, time required for polishing varies according to an aqueous dispersion and polishing apparatus used for polishing, and it is very inefficient to acquire polishing time empirically from each of polishings under various different conditions.

In contrast, a method of detecting a polishing end point by tracking a current value of a motor that rotates a platen of a chemical mechanical polishing apparatus has been proposed (Japanese Patent Application Laid-Open No. 203819/2002). This method determines the end point by detecting a change in current that is ascribable to a decrease in torque required for rotation of the platen as a result of elimination of initial bumps on a polished surface and flattening of the surface by polishing. With this method, it is impossible in principle to detect a true end point, i.e. a point when a material to be removed is completely removed by polishing. Further, an optical end-point detection device and method using an optical method capable of directly observing the condition of a polished surface have been studied (for example, Japanese Patent Application Laid-Open Nos. 7985/1997 and326220/2000) However, the optical end-point detection method is difficult to apply since it lacks reliability of end-point detection in removal of an insulating layer in the chemical mechanical polishing step of the STI.

Further, in chemical mechanical polishing, a reduction in polishing wastewater disposal costs is desired.

To reduce the polishing wastewater disposal costs, it is conceived to reduce the amount of abrasives contained in an aqueous dispersion to be used. However, when a conventionally known aqueous dispersion for chemical mechanical polishing is used in a diluted state for the purpose of reducing the amount of abrasives used, a significant reduction in polishing rate occurs, resulting in an increase in the amount of abrasives required for polishing and removing a predetermined amount of object to be polished.

No aqueous dispersions for chemical mechanical polishing have heretofore been known that can provide a polished surface having a high degree of surface smoothness at a high removal rate even if the content of abrasives is reduced and can achieve a reduction is polishing wastewater disposal costs from the viewpoint.

### DISCLOSURE OF THE INVENTION

The present invention has been conceived in view of the above circumstances, and an object thereof is to provide an aqueous dispersion for chemical mechanical polishing which shows a high removal rate even when the content of abrasives is low and generates substantially no polishing scratches on a polished surface, particularly in a chemical mechanical polishing step of STI, and a method for producing the aqueous dispersion.

Another object of the present invention is to provide a chemical mechanical polishing method that can determine a polishing end point easily, without using an optical end-point detection device, particularly in the chemical mechanical polishing step of STI.

According to the present invention, firstly, the above objects of the present invention are achieved by an aqueous dispersion for chemical mechanical polishing that comprises abrasives comprising (A) 100 parts by weight of inorganic particles comprising ceria, (B) 5 to 100 parts by weight of cationic organic polymer particles and (C) 5 to 120 parts by weight of anionic water-soluble compound.

According to the present invention, secondly, the above objects of the present invention are achieved by a method for producing the above aqueous dispersion for chemical mechanical polishing, comprising a step of adding a second liquid comprising (C) 5 to 30 wt % of anionic water-soluble compound to a first liquid comprising (A) 0.1 to 10 wt % of inorganic particles comprising ceria and (B) 5 to 100 parts by weight of cationic organic polymer particles based on 100 parts by weight of the inorganic particles (A).

According to the present invention, thirdly, the above objects of the present invention are achieved by a chemical mechanical polishing method comprising polishing a surface to be polished of an object to be polished by use of the above aqueous dispersion for chemical mechanical polishing.

### BRIEF DESCRIPTION OF THE DRAWINGS

FIG. 1 is a schematic cross-sectional diagram illustrating an example of an object to be polished for a chemical mechanical polishing method according to the present invention.

FIG. 2 is a graph illustrating changes with time in current values of motors that rotate the platens of chemical mechanical polishing apparatuses in Example 17 and Comparative Example 9.

FIG. 3 shows an electron micrograph of abrasives taken in Example 18, wherein FIG. 3(a) is an electron micrograph and FIG. 3(b) is a reference diagram for understanding the electron micrograph.

### DESCRIPTION OF SYMBOLS

1 silicon substrate

2 grooves

3 silicon oxide layer

4 silicon nitride layer

5 insulation film

10 object to be polished

### BEST MODE FOR CARRYING OUT THE INVENTION

### Aqueous Dispersion for Chemical Mechanical Polishing

An aqueous dispersion for chemical mechanical polishing according to the present invention contains abrasives comprising (A) inorganic particles comprising ceria, (B) cationic organic polymer particles and (C) an anionic water-soluble compound. Hereinafter, the components that constitute the abrasives contained in the aqueous dispersion for chemical mechanical polishing of the present invention will be described.

### (A) Inorganic Particles Comprising Ceria

The above inorganic particles comprising ceria (A) (hereinafter may be referred to as “inorganic particles (A)”) may comprise ceria alone or may be a mixture of ceria and other inorganic particles. Illustrative examples of the other inorganic particles include silica, alumina, titania, zirconia, manganese dioxide, dimanganese trioxide, and iron oxide. Of these, silica is preferred.

The above ceria can be obtained by, for example, heat-treating a tetravalent cerium compound in an oxidizing atmosphere at 600 to 800° C. Illustrative examples of the tetravalent cerium compound that is a raw material for the ceria include cerium hydroxide, cerium carbonate, and cerium oxalate.

The specific surface area of the ceria is preferably 5 to 100 m²/g, more preferably 10 to 70 m²/g, much more preferably 10 to 30 m²/g. By using inorganic particles comprising ceria having a specific surface area falling within this range, an aqueous dispersion for chemical mechanical polishing that provides a polished surface having excellent flatness can be obtained.

Illustrative examples of the above silica include fumed silica, and colloidal silica. The above fumed silica can be obtained by, for example, reacting silicon chloride in the presence of hydrogen and oxygen. The colloidal silica can be obtained by a method of ion-exchanging a silicate compound or a method of hydrolyzing an alkoxysilicon compound and undergoing a condensation reaction, for example.

When the inorganic particles (A) are a mixture of the ceria and other inorganic particles, the proportion of the ceria in all inorganic particles is preferably not lower than 60 wt %, more preferably not lower than 90 wt %.

The inorganic particles (A) are preferably inorganic particles comprising the ceria alone or inorganic particles comprising the ceria and silica and more preferably inorganic particles comprising the ceria alone.

The average particle diameter of the inorganic particles (A) is preferably 0.01 to 1 μm, more preferably 0.02 to 0.7 μm, much more preferably 0.04 to 0.3 μm. This average particle diameter can be measured by a dynamic light scattering method, a laser scattering diffraction method, observation under a transmission electron microscope, or the like. Of these, measurement by the laser scattering diffraction method is preferred because it is easy.

The pore volume of the inorganic particles (A) is preferably 0.09 to 0.20 mL/g, more preferably 0.10 to 0.14 mL/g. The pore volume can be known by a gaseous adsorption method or the like.

By using inorganic particles having an average particle diameter and pore volume falling within the above ranges, abrasives showing an excellent balance between a removal rate and dispersion stability in the aqueous dispersion can be obtained.

### (B) Cationic Organic Polymer Particles

The above cationic organic polymer particles (B) are organic particles having a cationic group in the particles. Illustrative examples of the cationic group include groups represented by the following formulas (1) to (4).

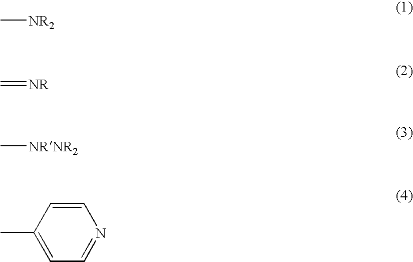

In the above formulas, Rs are each independently a hydrogen atom, an aliphatic hydrocarbon group having 1 to 30 carbon atoms or an aryl group having 6 to 30 carbon atoms, preferably a hydrogen atom or an alkyl group having 1 to 4 carbon atoms, more preferably a hydrogen atom or a methyl group. Further, R′ is a hydrogen atom, an aliphatic hydrocarbon group having 1 to 30 carbon atoms or an aryl group having 6 to 30 carbon atoms.

The above cationic organic polymer particles (B) are not particularly limited as long as they have such a cationic group as described above. For example, they may be polymer particles having such a cationic group as described above, polymer particles having a surfactant containing such a cationic group as described above attached thereto, or the like.

When the cationic organic particles (B) are polymer particles having a cationic group, the above cationic group can be positioned in a side chain and at at least one end of the polymer.

A polymer having a cationic group in a side chain can be obtained by homopolymerization of cationic monomer or copolymerization of two or more cationic monomers or copolymerization of cationic monomer(s) and other monomer(s).

Illustrative examples of the above cationic monomer include (meth)acrylic ester having an aminoalkyl group, (meth)acrylic ester having an aminoalkoxyalkyl group, amide(meth)acrylate or N-alkyl-substituted amide(meth)acrylate, and (meth)acrylic ester containing an N-aminoalkyl group.

Specific examples of the (meth)acrylic ester having an aminoalkyl group include 2-dimethylaminoethyl(meth)acrylate, 2-diethylaminoethyl(meth)acrylate, 2-dimethylaminopropyl(meth)acrylate, and 3-dimethylaminopropyl(meth)acrylate. Specific examples of the (meth)acrylic ester having an aminoalkoxyalkyl group include 2-(dimethylaminoethoxy)ethyl(meth)acrylate, 2-(diethylaminoethoxy)ethyl(meth)acrylate, and 3-(dimethylaminoethoxy)propyl(meth)acrylate. Specific examples of the amide(meth)acrylate or N-alkyl-substituted amide(meth)acrylate include (meth)acrylamide and methyl(meth)acrylamide. Specific examples of the (meth)acrylic ester containing an N-aminoalkyl group include N-(2-dimethylaminoethyl)(meth)acrylamide, N-(2-diethylaminoethyl)(meth)acrylamide, N-(2-dimethylaminopropyl)(meth)acrylamide, and N-(3-dimethylaminopropyl)(meth)acrylamide.

Of these, 2-dimethylaminoethyl(meth)acrylate and N-(2-dimethylaminoethyl)(meth)acrylamide are preferred.

Further, these cationic monomers may be in the form of a salt having methyl chloride, dimethyl sulfate, diethyl sulfate or the like added thereto. When the cationic monomers are these salts, the salt having methyl chloride added thereto is preferred.

Illustrative examples of the above other monomers include an aromatic vinyl compound, unsaturated nitrile compound, (meth)acrylic ester (excluding those corresponding to the above cationic monomers), a conjugated diene compound, carboxylic acid vinyl ester, and halogenated vinylidene.

Specific examples of the aromatic vinyl compound include styrene, α-methylstyrene, p-methylstyrene, and halogenated styrene. Specific examples of the unsaturated nitrile compound include acrylonitrile. Specific examples of the (meth)acrylic ester (excluding those corresponding to the above cationic monomers) include methyl(meth)acrylate, ethyl(meth)acrylate, butyl(meth)acrylate, cyclohexyl(meth)acrylate, 2-ethylhexyl(meth)acrylate, lauryl(meth)acrylate, glycidyl(meth)acrylate, and 2-hydroxyethyl(meth)acrylate. Specific examples of the conjugated diene compound include butadiene and isoprene. Specific examples of the carboxylic acid vinyl ester include vinyl acetate. Specific examples of the halogenated vinylidene include vinyl chloride and vinylidene chloride.

Of these, styrene, α-methylstyrene, acrylonitrile, methyl methacrylate, butyl methacrylate, 2-hydroxyethyl acrylate and trimethylolpropane trimethacrylate are preferred.

Further, a monomer having two or more polymerizable unsaturated bonds may also be copolymerized as required.

Illustrative examples of such a monomer include divinylbenzene, divinylbiphenyl, ethylene glycol di(meth)acrylate, diethylene glycol di(meth)acrylate, triethylene glycol di(meth)acrylate, tetraethylene glycol di(meth)acrylate, propylene glycol di(meth)acrylate, dipropylene glycol di(meth)acrylate, tripropylene glycol di(meth)acrylate, tetrapropylene glycol di(meth)acrylate, 1,4-butanediol di(meth)acrylate, 1,6-hexanediol di(meth)acrylate, neopentyl glycol di(meth)acrylate, 2,2′-bis[4-(meth)acryloyloxypropioxyphenyl]propane, 2,2′-bis[4-(meth)acryloyloxydiethoxydiphenyl]propane, glycerin tri(meth)acrylate, trimethylolpropane tri(meth)acrylate, and pentaerythritol tetra(meth)acrylate.

Of these, divinylbenzene and ethylene glycol dimethacrylate are preferred.

When the cationic organic particles (B) are a copolymer of cationic monomer(s) and other monomer(s) the proportion of the cationic monomer used as a raw material is preferably 0.1 to 60 wt %, more preferably 0.1 to 20 wt %, based on all monomers.

Such a polymer as described above can be produced by a known method, using a radical polymerization initiator. Illustrative examples of the radical polymerization initiator include benzoyl peroxide, potassium persulfate, ammonium persulfate, and 2,2′-azobisisobutyronitrile. The radical polymerization initiator is used in an amount of preferably 0.05 to 3.0 parts by weight, more preferably 0.1 to 2.0 parts by weight, based on 100 parts by weight of the total amount of the monomers.

The above polymer having a cationic group at the end of the polymer can be produced by using a polymerization initiator (hereinafter may be referred to as “cationic polymerization initiator”) having a group that remains at the end of the polymer as a polymerization initiator and becomes a cationic group when such a monomer as described above is polymerized. Further, a monomer having two or more polymerizable unsaturated bonds may be copolymerized as required.

The monomer which is a raw material in this case can be produced by homopolymerization or copolymerization of at least one monomer selected from the above cationic monomers and other monomers. When cationic monomers are used as some or all of raw material monomers, a polymer having a cationic group in a side chain and at the ends of the polymer can be obtained.

Illustrative examples of the above cationic polymerization initiators include 2,2′-azobis(2-methyl-N-phenylpropionamidine)dihydrochloride (sold under the trade name “VA-545” from Wako Pure Chemical Industries, Ltd.), 2,2′-azobis[N-(4-chlorophenyl)-2-methylpropionamidine]dihydrochloride (sold under the trade name “VA-546” from Wako Pure Chemical Industries, Ltd.), 2,2′-azobis[N-(4-hydroxyphenyl)-2-methylpropionamidine]dihydrochloride (sold under the trade name “VA-548” from Wako Pure Chemical Industries, Ltd.), 2,2′-azobis[2-methyl-N-(phenylmethyl)-propionamidine]dihydrochloride (sold under the trade name “VA-552” from Wako Pure Chemical Industries, Ltd.), 2,2′-azobis[2-methyl-N-(2-propenyl)propionamidine]dihydrochloride (sold under the trade name “VA-553” from Wako Pure Chemical Industries, Ltd.), 2,2′-azobis(2-methylpropionamidine)dihydrochloride (sold under the trade name “V-50” from Wako Pure Chemical Industries, Ltd.), 2,2′-azobis[N-(2-hydroxyethyl)-2-methylpropionamidine]dihydrochloride (sold under the trade name “VA-558” from Wako Pure Chemical Industries, Ltd.), 2,2′-azobis[N-(2-carboxyethyl)-2-methylpropionamidine]hydrate (sold under the trade name “VA-057” from Wako Pure Chemical Industries, Ltd.), 2,2′-azobis[2-methyl-(5-methyl-2-imidazoline-2-yl)propane]dihydrochloride (sold under the trade name “VA-041” from Wako Pure Chemical Industries, Ltd.), 2,2′-azobis[2-(2-imidazoline-2-yl)propane]dihydrochloride (sold under the trade name “VA-044” from Wako Pure Chemical Industries, Ltd.), 2,2′-azobis[2-(4,5,6,7-tetrahydro-1H-1,3-diazepine-2-yl)propane]dihydrochloride (sold under the trade name “VA-054” from Wako Pure Chemical Industries, Ltd.), 2,2′-azobis[2-(3,4,5,6-tetrahydropyrimidine-2-yl)propane]dihydrochloride (sold under the trade name “VA-058” from Wako Pure Chemical Industries, Ltd.), 2,2′-azobis[2-(5-hydroxy-3,4,5,6-tetrahydropyrimidine-2-yl) propane]dihydrochloride (sold under the trade name “VA-059” from Wako Pure Chemical Industries, Ltd.), 2,2′-azobis{2-[1-(2-hydroxyethyl)-2-imidazoline-2-yl]propane}dihydrochloride (sold under the trade name “VA-060” from Wako Pure Chemical Industries, Ltd.), and 2,2′-azobis[2-(2-imidazoline-2-yl)propane] (sold under the trade name “VA-061” from Wako Pure Chemical Industries, Ltd.).

Of these, 2,2′-azobis(2-methylpropionamidine)dihydrochloride (trade name “V-50”), 2,2′-azobis[N-(2-carboxyethyl)-2-methylpropionamidine]hydrate (trade name “VA-057”) and 2,2′-azobis[2-(2-imidazoline-2-yl)propane]dihydrochloride (trade name “VA-044”) are preferably used.

The cationic polymerization initiator is used in an amount of preferably 0.1 to 5.0 parts by weight, more preferably 0.2 to 3.0 parts by weight, much more preferably 0.5 to 2.0 parts by weight, based on 100 parts by weight of the total amount of the monomers.

When the cationic organic polymer particles (B) are polymer particles having a surfactant containing a cationic group attached thereto, the polymer preferably has a neutral or anionic group. Such a polymer can be produced from the above “other monomer” or from the above “other monomer” and “monomer having two or more polymerizable unsaturated bonds”, in accordance with a known method, using such a radical polymerization initiator as described above (not the above cationic polymerization initiator).

As a monomer having an anionic group, the above carboxylic acid vinyl ester can be used, for example. The monomer having an anionic group is used in an amount of preferably 1 to 60 wt %, more preferably 1 to 30 wt %, based on all monomers.

In this case, the radical polymerization initiator is used in an amount of preferably 0.05 to 3.0 parts by weight, more preferably 0.1 to 2.0 parts by weight, based on 100 parts by weight of the total amount of the monomers.

Illustrative examples of the above surfactant having a cationic group include alkylpyridinyl chloride, alkylamine acetate, alkylammonium chloride and alkyneamine, as well as a reactive cationic surfactant such as diallyl ammonium halide as described in Japanese Patent Application Laid-Open No. 235631/1985.

The surfactant having a cationic group is used in an amount of preferably 1 to 30 parts by weight, more preferably 1 to 10 parts by weight, based on 100 parts by weight of the polymer.

To attach the surfactant having a cationic group to the polymer, an appropriate method can be used. For example, it can be achieved by preparing a dispersion containing the polymer particles and adding a solution of the surfactant to the dispersion.

The average particle diameter of the cationic organic polymer particles (B) is preferably not larger than 1.0 μm, more preferably 0.02 to 0.6 μm, particularly preferably 0.04 to 0.3 μm. Further, this average particle diameter is preferably about the same as the average particle diameter of the inorganic particles (A), more preferably 60 to 200% of the average particle diameter of the inorganic particles (A), particularly preferably 60 to 100% of the average particle diameter of the inorganic particles (A). The above average particle diameter can be measured by a dynamic light scattering method, a laser scattering diffraction method, observation under a transmission electron microscope, or the like.

### (C) Anionic Water-Soluble Compound

Illustrative examples of an anionic functional group contained in the above anionic water-soluble compound (C) include a carboxyl group and a sulfone group.

The anionic water-soluble compound (C) is preferably an anionic water-soluble polymer or anionic surfactant.

Illustrative examples of an anionic water-soluble polymer containing a carboxyl group as an anionic functional group include a (co)polymer of an unsaturated carboxylic acid, polyglutamic acid, and polymaleic acid. Illustrative examples of an anionic water-soluble polymer containing a sulfone group as an anionic group include a (co)polymer of unsaturated monomer having a sulfone group.

The above (co)polymer of unsaturated carboxylic acid is a homopolymer of unsaturated carboxylic acid or a copolymer of unsaturated carboxylic acid and other monomer. Illustrative examples of the unsaturated carboxylic acid include (meth)acrylic acid. Illustrative examples of the other monomer include (meth)acrylamide, (meth)acrylic ester, styrene, butadiene, and isoprene. Specific examples of the (meth)acrylic ester include methyl(meth)acrylate, ethyl(meth)acrylate, and benzyl(meth)acrylate.

The above (co)polymer of unsaturated monomer having a sulfone group is a homopolymer of unsaturated monomer having a sulfone group or a copolymer of unsaturated monomer having a sulfone group and other monomer. Illustrative examples of the unsaturated monomer having a sulfone group include styrenesulfonic acid, naphthalenesulfonic acid, and isoprenesulfonic acid. As the other monomer, the same monomers as the other monomers presented as examples of a raw material of the above unsaturated carboxylic copolymer can be used.

Of these anionic water-soluble polymers, the (co)polymer of unsaturated carboxylic acid can be preferably used, and poly(meth)acrylic acid is particularly preferred.

Further, as these water-soluble organic polymers having anionic groups, those in which all or some of anionic groups are salts may be used. Illustrative examples of counter cations in that case include ammonium ions, alkylammonium ions, and potassium ions. Of these, the ammonium ions or alkylammonium ions are preferred.

The weight average molecular weight (Mw) in terms of polyethylene glycol of the anionic water-soluble polymer that is measured by gel permeation chromatography (GPC) using water as a solvent is preferably 3,000 to 30,000, more preferably 4,000 to 25,000, much more preferably 5,000 to 20,000. When an anionic water-soluble polymer having a weight average molecular weight within this range, an effect of further reducing generation of surface defects on a polished surface is developed effectively.

Illustrative examples of the above anionic surfactant include alkylbenzene sulfonate, alkyl diphenyl ether disulfonate, alkyl sulfosuccinate, and alkyl ether sulfate. Illustrative examples of counter cations of these anionic surfactants include ammonium ions, alkylammonium ions, and potassium ions.

Of these, a salt of dodecylbenzene sulfonic acid or a salt of alkyl diphenyl ether disulfonic acid is preferred, ammonium salts thereof are more preferred.

As the anionic water-soluble compound (C) used in the present invention, an anionic water-soluble polymer is preferred.

The abrasives contained in the aqueous dispersion for chemical mechanical polishing according to the present invention comprises 100 parts by weight of the inorganic particles comprising ceria (A), 5 to 100 parts by weight of the cationic organic polymer particles (B) and 5 to 120 parts by weight of the anionic water-soluble compound (C).

The cationic organic polymer particles (B) are preferably 10 to 80 parts by weight, more preferably 15 to 60 parts by weight, based on 100 parts by weight of the inorganic particles (A). The anionic water-soluble compound (C) is preferably 10 to 50 parts by weight, more preferably 15 to 40 parts by weight, based on 100 parts by weight of the inorganic particles (A).

It has been found by observation under an electron microscope that the above abrasives are in a peculiar aggregate state in which the inorganic particles (A) and the cationic organic polymer particles (B) are aggregated via the anionic water-soluble compound (C).

The amount of the abrasives contained in the aqueous dispersion for chemical mechanical polishing according to the present invention is preferably 0.1 to 2.0 wt %, more preferably 0.2 to 0.8 wt %, based on the total amount of the aqueous dispersion.

Although the aqueous dispersion for chemical mechanical polishing according to the present invention contains the above abrasives as an essential component, it may also contain an acid, base, preservative or the like as required.

As the above acid, an organic acid or inorganic acid can be used. Illustrative examples of the organic acid include p-toluenesulfonic acid, isoprenesulfonic acid, gluconic acid, lactic acid, citric acid, tartaric acid, malic acid, glycolic acid, malonic acid, formic acid, oxalic acid, succinic acid, fumaric acid, maleic acid, and phthalic acid. Illustrative examples of the inorganic acid include nitric acid, hydrochloric acid and sulfuric acid. These acids are added in an amount of preferably not larger than 2 wt %, more preferably not larger than 1 wt %, based on the whole aqueous dispersion for chemical mechanical polishing.

The above base is not particularly limited, and an organic base or inorganic base can be used. Illustrative examples of the organic base include nitrogen-containing organic compounds such as ethylenediamine, ethanolamine and tetramethylammonium hydroxide. Illustrative examples of the inorganic base include ammonia, potassium hydroxide, sodium hydroxide, and lithium hydroxide. The content of the above base is preferably not higher than 1 wt %, more preferably not higher than 0.5 wt %, based on the whole aqueous dispersion for chemical mechanical polishing.

Illustrative examples of the above preservative include a bromonitroalcohol compound and an isothiazolone compound. Specific examples of the bromonitroalcohol compound include 2-bromo-2-nitro-1,3-propanediol, 2-bromo-2-nitro-1,3-butanediol, 2,2-dibromo-2-nitroethanol, and 2,2-dibromo-3-nitrilopropion amide. Specific examples of the isothiazolone compound include 1,2-benzoisothiazolone-3-one, 5-chloro-2-methyl-4-isothiazolone-3-one, 2-methyl-4-isothiazolone-3-one, 5-chloro-2-phenethyl-3-isothiazolone, 4-bromo-2-n-dodecyl-3-isothiazolone, 4,5-dichloro-2-n-octyl-3-isothiazolone, 4-methyl-5-chloro-2-(4′-chlorobenzyl)-3-isothiazolone, 4,5-dichloro-2-(4′-chlorobenzyl)-3-isothiazolone, 4,5-dichloro-2-(4′-chlorophenyl)-3-isothiazolone, 4,5-dichloro-2-(2′-methoxy-3′-chlorophenyl)-3-isothiazolone, 4,5-dibromo-2-(4′-chlorobenzyl)-3-isothiazolone, 4-methyl-5-chloro-2-(4′-hydroxyphenyl)-3-isothiazolone, 4,5-dichloro-2-n-hexyl-3-isothiazolone, and 5-chloro-2-(3′,4′-dichlorophenyl)-3-isothiazolone. Of these, 2-bromo-2-nitro-1,3-propanediol, 1,2-benzoisothiazolone-3-one, 5-chloro-2-methyl-4-isothiazolone-3-one or 2-methyl-4-isothiazolone-3-one is preferred.

The amount of the preservative used in the aqueous dispersion for chemical mechanical polishing according to the present invention is preferably not larger than 0.1 wt %, more preferably not larger than 0.01 wt %.

The aqueous dispersion for chemical mechanical polishing according to the present invention is an aqueous dispersion comprising the above abrasives as an essential component and an acid, base, preservative, etc. as arbitrarily added components.

Illustrative examples of a dispersion medium that can be used in the aqueous dispersion for chemical mechanical polishing according to the present invention include water, and a mixed solvent comprising water and a water-soluble alcohol. Illustrative examples of the water-soluble alcohol include methanol, ethanol, and isopropanol. Of these, water is preferably used as a medium at the time of production of polishing agent.

The pH of the aqueous dispersion for chemical mechanical polishing according to the present invention is preferably 4.0 to 9.0, more preferably 5.0 to 8.5, much more preferably 5.5 to 8.0.

As is obvious from Examples to be described later, the aqueous dispersion for chemical mechanical polishing according to the present invention that contains the abrasives comprising the components (A) (B) and (C) in the above amounts generates substantially no polishing scratches on a polished surface and makes higher removal rate possible and can be very suitably used particularly for polishing of an insulation film in a shallow trench isolation step (STI step) and polishing of an interlayer insulation film of multilayer wiring substrate.

### Method for Producing Aqueous Dispersion for Chemical Mechanical Polishing

The aqueous dispersion for chemical mechanical polishing according to the present invention can be produced by a method comprising a step of adding a second liquid comprising (C) 5 to 30 wt % of anionic water-soluble compound to a first liquid comprising (A) 0.1 to 10 wt % of inorganic particles comprising ceria and (B) 5 to 100 parts by weight of cationic organic polymer particles based on 100 parts by weight of the inorganic particles (A).

The first liquid is an aqueous dispersion. As its dispersion medium, water is preferably used, as in the case of the desired dispersion medium for the aqueous dispersion for chemical mechanical polishing. The content of the inorganic particles comprising ceria (A) in the first liquid is preferably 0.25 to 7.5 wt %. The content of the cationic organic polymer particles (B) in the first liquid can be determined according to a desired ratio of the inorganic particles (A) and the polymer particles (B) in the abrasives contained in the aqueous dispersion for chemical mechanical polishing and is preferably 10 to 80 parts by weight, more preferably 15 to 60 parts by weight, based on 100 parts by weight of the inorganic particles (A) contained in the first liquid. The pH of the first liquid is preferably 3.5 to 9.0, more preferably 4.0 to 8.0, much more preferably 4.5 to 6.0. The first liquid can contain the above acid or base to have its pH fall within the above preferred pH range.

The first liquid may be prepared by any of (1) a method comprising preparing an aqueous dispersion containing the inorganic particles (A) and an aqueous dispersion containing the polymer particles (B) and mixing them together, (2) a method comprising preparing an aqueous dispersion containing one of the inorganic particles (A) and the polymer particles (B) and mixing the other in solid form (powder form) into the dispersion, and (3) a method comprising mixing the particles (A) and (B) together in solid form (powder form) and then dispersing the mixture into an aqueous medium. Of these methods, the above method (1) is preferred.

The second liquid is a solution. As its solvent, water is preferably used, as in the case of the desired dispersion medium for the aqueous dispersion for chemical mechanical polishing. The amount of the anionic water-soluble compound (C) contained in the second liquid is preferably 10 to 25 wt %, more preferably 15 to 20 wt %. The pH of the second liquid is preferably 4.0 to 9.0, more preferably 5.0 to 8.0, much more preferably 5.5 to 7.0. The second liquid can contain the above acid or base to have its pH fall within the above preferred pH range.

With the contents of the components contained in the first liquid and the second liquid within the above preferred ranges, the aqueous dispersion for chemical mechanical polishing according to the present invention that contains abrasives of uniform composition in proper amounts or a concentrate thereof can be obtained easily by use of these liquids.

The aqueous dispersion for chemical mechanical polishing according to the present invention can be produced by preparing the first liquid and second liquid prepared as described above, adding the second liquid to the first liquid which is preferably being agitated, adding the arbitrarily added components as required, and diluting the solution as required to adjust the content of the abrasives.

After the first liquid and the second liquid are mixed together, an acid or base may be further added to adjust the pH of the aqueous dispersion for chemical mechanical polishing.

Further, when the aqueous dispersion for chemical mechanical polishing according to the present invention contains the above preservative, the preservative may be contained in one or both of the first and second liquids in advance. Alternatively, it is also possible to add the preservative after mixing the first and second liquids that contain no preservative together. Of these, it is preferred to mix the preservative into the first liquid in advance.

The thus prepared aqueous dispersion may be subjected to a chemical mechanical polishing step after filtered with a filter having a pore diameter of about 2 to 10 μm.

As to the aqueous dispersion for chemical mechanical polishing according to the present invention, it is preferred to produce and store a set of the above first liquid and second liquid and use an aqueous dispersion for chemical mechanical polishing produced by such a method as described above at a point of time close to the chemical mechanical polishing step, rather than produce, store and use an aqueous dispersion containing all of the above components (A), (B) and (C) or a concentrate thereof.

The set for producing the aqueous dispersion for chemical mechanical polishing comprises the first and second liquids used in the above method for producing the aqueous dispersion for chemical mechanical polishing. The first liquid or the second liquid or both may be prepared in a concentrated form with the content of each component contained in each liquid maintained.

Therefore, the set for producing the aqueous dispersion for chemical mechanical polishing according to the present invention comprises:
the first liquid comprising 100 parts by weight of the inorganic particles comprising ceria (A) and 5 to 100 parts by weight of the cationic organic polymer particles (B), and
the second liquid comprising the anionic water-soluble compound (C).

When the first liquid included in the set is a concentrate, the contents of the inorganic particles comprising ceria (A) and the cationic organic polymer particles (B) in this first liquid are preferably not higher than 30 wt %, more preferably not higher than 20 wt %. With the contents of the inorganic particles (A) and the cationic organic polymer particles (B) in the concentrate which is the first liquid within the above ranges, even after the first liquid is stored for a long time, the particles do not precipitate in the first liquid or can be redispersed easily even if precipitation occurs, so that the first liquid can be subjected to production of the aqueous dispersion for chemical mechanical polishing according to the present invention easily after diluted. Therefore, the content of the inorganic particles comprising ceria (A) in the first liquid of the set is preferably 1 to 30 wt %, more preferably 2.5 to 20 wt %.

Meanwhile, when the second liquid included in the set is a concentrate, the content of the anionic water-soluble compound (C) in this second liquid is preferably not higher than 40 wt %. With the content of the anionic water-soluble compound (C) in the concentrate which is the second liquid within the above range, the second liquid can be a uniform and stable solution, and even after stored for a long time, the second liquid can be suitably subjected to production of the aqueous dispersion for chemical mechanical polishing according to the present invention after diluted. Therefore, the content of the anionic water-soluble compound (C) in the second liquid of the set is preferably 5 to 40 wt %.

Further, time from production of the aqueous dispersion for chemical mechanical polishing according to the present invention to the chemical mechanical polishing step is preferably within 60 days, more preferably within 15 days. Meanwhile, when the set comprising the two liquids is stored, it can be stored stably for at least about one year in a normal storage environment, and it can produce an aqueous dispersion for chemical mechanical polishing which gives desired performance in accordance with the above method after stored.

### Chemical Mechanical Polishing Method

The chemical mechanical polishing method of the present invention polishes an object to be polished by use of the above aqueous dispersion for chemical mechanical polishing. A preferred material that constitutes a surface to be polished of the object to be polished is an insulation film. Specific examples thereof include an insulation film that is polished in the shallow trench isolation (STI) step, and an interlayer insulation film of multilayer wiring substrate.

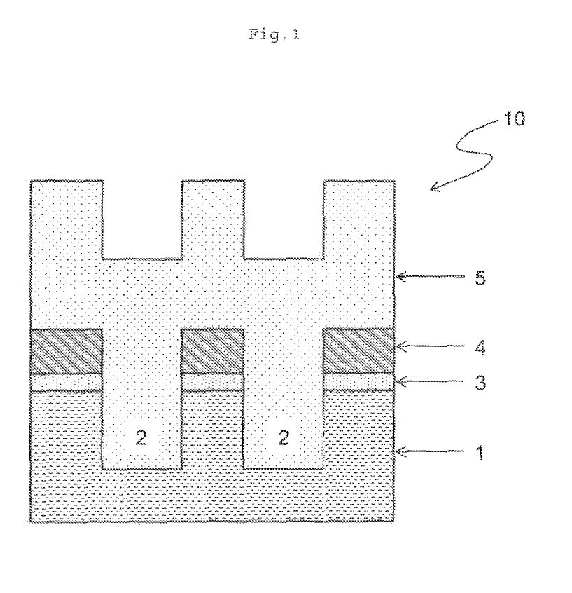

An example of an object to be polished in the STI step is such an object to be polished as shown as a schematic cross-sectional diagram in FIG. 1. An object to be polished 10 in FIG. 1 is an object to be polished wherein a silicon oxide layer 3 is formed on a surface, excluding grooves 2, of a silicon substrate 1 having the grooves which are to become device separation regions, a silicon nitride layer 4 is formed on the layer 3, and an insulation film 5 is deposited on the grooves 2 and the silicon nitride layer 4. The object to be polished in FIG. 1 is ideally polished in the STI step until the silicon nitride layer 4 is exposed.

Illustrative examples of materials that constitute the insulation film to be polished in the above STI step and the insulation film of multilayer wiring substrate include a thermally oxidized film, PETEOS film (Plasma Enhanced-TEOS film), HDP film (High Density Plasma Enhanced-TEOS film), silicon oxide film obtained by a thermal chemical vapor deposition method (thermal CVD method), boron phosphor silicate film (BPSG film), and fluorinated silicate film (FSG film).

The above thermally oxidized film is formed by exposing high-temperature silicon to an oxidizing atmosphere to chemically react the silicon with oxygen or with water.

The above PETEOS film is formed by chemical vapor deposition using tetraethyl orthosilicate (TEOS) as a raw material and plasma as an acceleration condition.

The above HDP film is formed by chemical vapor deposition using tetraethyl orthosilicate (TEOS) as a raw material and high-density plasma as an acceleration condition.

The above silicon oxide film obtained by a thermal CVD method is formed by an ambient-pressure CVD method (AP-CVD method) or low-pressure CVD method (LP-CVD method).

The above boron phosphor silicate film (BPSG film) is formed by an ambient-pressure CVD method (AP-CVD method) or low-pressure CVD method (LP-CVD method).

Further, the above fluorinated silicate film is formed by chemical vapor deposition using high-density plasma as an acceleration condition.

The chemical mechanical polishing method of the present invention can be carried out under proper conditions by use of a commercial chemical mechanical polishing apparatus. Illustrative examples of the commercial chemical mechanical polishing apparatus include “EPO-112” and “EPO-222” (products of Ebara Corporation) and “Mirra-Mesa” (product of Applied Materials, Inc.).

In the chemical mechanical polishing method of the present invention, when such an object to be polished as shown in FIG. 1 is to be polished, the end point of chemical mechanical polishing can be easily known by tracking a current value of a motor that rotates a platen of a chemical mechanical polishing apparatus.

That is, in the chemical mechanical polishing method of the present invention, a tendency that the above current value gradually increases first is seen, excluding an unstable period in the initial stage of polishing (e.g. about 2 to 5 seconds immediately after the start of polishing). As polishing of an object to be polished proceeds, initial unevenness on a surface to be polished is eliminated, and the contact area between a polishing pad and the object to be polished increases, whereby friction increases. It is assumed that this causes the above increasing tendency. Then, as the polishing further proceeds, the current value turns to a decreasing tendency. It has been found that a point where the current value shows an inflection point after turning from the increasing tendency to the decreasing tendency in a graph illustrating changes with time in the current value matches the end point of the chemical mechanical polishing step, i.e. a point where the silicon nitride layer 4 is exposed. This point is a point which satisfies the following expression (1):

d²A/dt²=0 (1)

(wherein A is a current value of a motor that rotates a platen of a chemical mechanical polishing apparatus, and t is time)
for the first time after the current value turns from the increasing tendency to the decreasing tendency.

Meanwhile, as to conventionally known ceria abrasives, no distinct correlation is observed between a current value of a motor that rotates a platen and the end point of polishing.

### Examples

### Preparation of Water Dispersion of Ceria

Cerium carbonate was heated in air at 700° C. for 4 hours to obtain ceria. This ceria was mixed with ion exchange water and pulverized by means of bead mills using zirconia beads. This was left to stand for 72 hours and classified by isolating an upper portion equivalent to 90 wt % to obtain a ceria water dispersion containing 28.7 wt % of ceria.

When the average particle diameter of the ceria in this water dispersion was measured by a laser diffraction method, it was 140 nm. Further, the pore volume of ceria obtained by drying the above ceria water dispersion was measured by a gaseous adsorption method using helium, it was 0.105 mL/g, and when the specific surface area of the cerium was measured by a BET method using nitrogen, it was 15.4 m²/g.

### Preparation of Cationic Organic Polymer Particles

### Synthesis Example 1

### Preparation of Organic Particles (a)

60 parts by weight of methyl methacrylate and 40 parts by weight of styrene as monomers, 0.5 parts by weight of 2,2′-azobis(2-methylpropionamidine)dihydrochloride (trade name “V-50”, product of Wako Pure Chemical Industries, Ltd.) as a polymerization initiator, 1 part by weight of nonionic surfactant “ADEKA SOAP ER-10” (product of ADEKA CORPORATION) as a surfactant and 400 parts by weight of ion exchange water were mixed together, heated to 70° C. under agitation in a nitrogen gas atmosphere and polymerized at 70° C. for 5 hours to obtain a water dispersion containing 19.7 wt % of organic particles (a). The polymerization reaction conversion rate was 98.3%.

When the average particle diameter of the obtained organic particles (a) was measured by a laser diffraction method, it was 128 nm, and the zeta potential of the organic particles (a) was +20 mV.

### Synthesis Examples 2 to 6

### Preparations of Organic Particles (b) to (f)

The procedure of Synthesis Example 1 was repeated except that the kinds and amounts of the monomers, polymerization initiator and surfactant used were changed as shown in Table 1, so as to obtain water dispersions containing organic particles (b) to (f). The polymerization reaction conversion rate, the particle content of each water dispersion and the average particle diameter and zeta potential of each organic particles in each synthesis example are shown in Table 1.

TABLE 1

| | S. Ex. 1 | S. Ex. 2 | S. Ex. 3 | S. Ex. 4 | S. Ex. 5 | S. Ex. 6 |
|---|---|---|---|---|---|---|
| | Organic | Organic | Organic | Organic | Organic | Organic |
| | Particles | Particles | Particles | Particles | Particles | Particles |
| | (a) | (b) | (c) | (d) | (e) | (f) |
| Monomers | | | | | | |
| Methyl Methacrylate | 60 | 50 | 35 | 60 | 90 | 60 |
| Styrene | 40 | 30 | 64 | 33 | — | 28 |
| Acrylonitrile | — | 20 | — | — | — | — |
| Divinylbenzene | — | — | 1 | 5 | 5 | 10 |
| Methyl Methacrylamide | — | — | — | 2 | 5 | — |
| Methacrylic Acid | — | — | — | — | — | 2 |
| Polymerization Initiators | | | | | | |
| V-50 | 0.5 | 0.5 | 0.5 | 0.5 | 1 | — |
| Ammonium Persulfate | — | — | — | — | — | 0.5 |
| Surfactants | | | | | | |
| ER-10 | 1 | 1 | — | — | — | — |
| ER-30 | — | — | 0.5 | 1 | — | — |
| QUARTAMIN 24P | — | — | — | — | 5 | — |
| DBSA | — | — | — | — | — | 1 |
| General Physical Properties | | | | | | |
| Polymerization Reaction Conversion Rate | 98.3 | 97.4 | 98.6 | 98.9 | 97.9 | 97.9 |
| (%) | | | | | | |
| Average Particle Diameter (nm) | 128 | 119 | 268 | 55 | 130 | 145 |
| Zeta Potential (mV) | +20 | +20 | +18 | +23 | +28 | −32 |
| Particle Content (wt %) | 19.7 | 19.4 | 19.8 | 19.8 | 19.5 | 19.6 |

S. Ex.: Synthesis Example

Further, the abbreviations in Table 1 indicate the following.

### Polymerization Initiator

V-50: trade name, product of Wako Pure Chemical Industries, Ltd.

### 2,2′-azobis(2-methylpropiondiamine)dihydrochloride Surfactants

ER-10: trade name “ADEKA REASOAP ER-10”, product of ADEKA CORPORATION. Nonionic reactive surfactant.

ER-30: trade name “ADEKA REASOAP ER-30”, product of ADEKA CORPORATION. Nonionic reactive surfactant.

QUARTAMIN 24P: trade name, product of Kao Corporation, dodecyl trimethylammonium chloride.

DBSA: ammonium dodecylbenzene sulfonate.

Numbers corresponding to the components in Table 1 are amounts (parts by weight) in which the components were added in the polymerization reaction. “-” indicates that the component corresponding to the section was not added.

### Example 1

### (1) Preparation of Aqueous Dispersion for Chemical Mechanical Polishing

### (1-1) Preparation of First Liquid

To ion exchange water charged into a vessel in advance, the above prepared ceria water dispersion was added as the inorganic particles (A) and diluted such that the content of ceria in a first liquid became 6.25 wt %. To the resulting composition, the water dispersion containing the organic particles (a) as the cationic organic polymer particles (B) was added in such an amount that the content of the organic particles (a) in the first liquid became 0.625 wt %. This mixture was further agitated for 30 minutes to prepare the first liquid that was a water dispersion containing the inorganic particles (A) and the cationic organic polymer particles (B).

### (1-2) Preparation of Second Liquid

A second liquid that was an aqueous solution containing 10 wt % of ammonium polyacrylate having a weight average molecular weight Mw of 10,000 as the anionic water-soluble compound (C) was prepared.

### (1-3) Preparation of Aqueous Dispersion for Chemical Mechanical Polishing

With the above prepared first liquid under agitation, the second liquid was added to the first liquid in such an amount that the amount of the anionic water-soluble compound (C) was equivalent to 40 parts by weight based on 100 parts by weight of the inorganic particles (A) in the first liquid, and the mixture was further agitated for 30 minutes. This was filtered with a polypropylene depth filter having a pore diameter of 5 μm to obtain a concentrate of aqueous dispersion for chemical mechanical polishing that contained 7.5 wt % of abrasives (1) comprising 100 parts by weight (5.0 wt %) of ceria as the inorganic particles (A), 10 parts by weight (0.5 wt %) of the organic particles (a) as the cationic organic polymer particles (B) and 40 parts by weight (2.0 wt %) of ammoniumpolyacrylate as the anionic water-soluble compound (C).

After this concentrate was diluted such that the content of the abrasives (1) became 2.00 wt %, it was subjected to a chemical mechanical polishing test.

### (2) Chemical Mechanical Polishing Test

By use of the thus prepared aqueous dispersion for chemical mechanical polishing (diluted one), chemical mechanical polishing was conducted on a thermally-oxidized-film-coated wafer having a diameter of 8 inches that was an object to be polished under the following conditions.

polishing apparatus: product of Ebara Corporation, model “EPO-112”

polishing pad: product of Nitta Haas Incorporated, “IC1000/SUBA400”

aqueous dispersion feed rate: 200 mL/min revolution speed of platen: 100 rpm

revolution speed of polishing head: 107 rpm

polishing head pressing pressure: 350 hPa

### <Removal Rate Evaluation Method>

After the film thickness before polishing of the thermally-oxidized-film-coated wafer having a diameter of 8 inches that was an object to be polished was measured by an optical interferometrical film thickness meter “NanoSpec 6100” (product of Nanometrics Japan Incorporated) in advance, the wafer was polished for 1 minute under the above chemical mechanical polishing test conditions. The film thickness of the polished object was measured by use of the same optical interferometrical film thickness meter as used before the polishing to determine the difference between the film thickness before the polishing and the film thickness after the polishing, i.e. the film thickness decreased by the chemical mechanical polishing. When the removal rate was calculated from the decreased film thickness and the polishing time, the removal rate was 363 nm/min.

### <Method of Evaluating Scratches>

The thermally-oxidized-film-coated wafer having a diameter of 8 inches that was an object to be polished was polished for 2 minutes under the above chemical mechanical polishing test conditions. The polished surface was inspected for defects by a wafer defect inspection instrument “KLA2351” of KLA-Tencor Corporation. First, the number of “defects” counted by the “KLA2351” over the whole area of the polished surface of the wafer with a pixel size of 0.39 μm and a threshold of 20 was determined. Then, these “defects” were displayed on the display of the instrument sequentially, and when the number of scratches on the whole surface of the wafer was checked by determining whether each of the “defects” was a scratch, the number of the scratches was 15 per wafer. Of the defects counted by the wafer defect inspection instrument, those which are not scratches can be exemplified by attached dust, stains produced during manufacturing of the wafer, and the like.

### Examples 2 and 3

Aqueous dispersions for chemical mechanical polishing were prepared and chemical mechanical polishing tests were conducted in the same manner as in Example 1 except that the concentrate of aqueous dispersion for chemical mechanical polishing was diluted such that the content of the abrasives (1) became as shown in Table 6. The results are shown in Table 6.

### Examples 4 to 9

Concentrates of aqueous dispersions for chemical mechanical polishing which contained abrasives (2) to (7) were prepared in the same manner as in Example 1 except that the kinds and contents of the cationic organic polymer particles (B) in the first liquid and the anionic water-soluble compound (C) in the second liquid were changed as shown in Table 2 and that the mixing ratio of the first liquid and the second liquid was changed such that the contents of the components (A), (B) and (C) in the concentrate of aqueous dispersion for chemical mechanical polishing became as shown in Table 4.

Chemical mechanical polishing tests were conducted in the same manner as in Example 1 except that aqueous dispersions for chemical mechanical polishing prepared by diluting the above concentrates with ion exchange water to abrasive contents shown in Table 6 were used. The results are shown in Table 6.

### Example 10

(1-1) Preparation of Concentrate of First liquid

To ion exchange water charged into a vessel in advance, the above prepared ceria water dispersion was added as the inorganic particles (A) and diluted such that the content of ceria in a first liquid became 5.0 wt %. To the resulting composition, the water dispersion containing the organic particles (a) as the cationic organic polymer particles (B) was added in such an amount that the content of the organic particles (a) in the first liquid became 0.5 wt %. This mixture was further agitated for 30 minutes and then filtered by a polypropylene depth filter having a pore diameter of 5 μm to prepare a concentrate of the first liquid that was a water dispersion containing the inorganic particles (A) and the cationic organic polymer particles (B).

### (1-2) Preparation of Second Liquid

A second liquid that was an aqueous solution containing 30 wt % of ammonium polyacrylate having a weight average molecular weight Mw of 8,000 as the anionic water-soluble compound (C) was prepared.

### (1-3) Preparation of Aqueous Dispersion for Chemical Mechanical Polishing

To ion exchange water charged into a vessel in advance, the above prepared first liquid was added in such an amount that the content of the inorganic particles (A) in an aqueous dispersion for chemical mechanical polishing became 0.5 wt %. To the resulting composition, the second liquid was added in such an amount that the amount of the anionic water-soluble compound (C) was equivalent to 50 parts by weight based on 100 parts by weight of the inorganic particles (A) in the first liquid, and the mixture was further agitated for 30 minutes. Thereby, an aqueous dispersion for chemical mechanical polishing that contained 0.8 wt % of abrasives (8) comprising 100 parts by weight (0.5 wt %) of ceria as the inorganic particles (A), 10 parts by weight (0.05 wt %) of organic polymer particles (b) as the cationic organic polymer particles (B) and 50 parts by weight (0.25 wt %) of ammonium polyacrylate as the anionic water-soluble compound (C) was obtained.

### (2) Chemical Mechanical Polishing Test

A chemical mechanical polishing test was conducted in the same manner as in Example 1 by use of the above prepared aqueous dispersion for chemical mechanical polishing. The results are shown in Table 6.

### Examples 11 to 16, Comparative Examples 1 to 3

Concentrates of the first liquids were prepared in the same manner as in Example 10 except that the content of the inorganic particles (A) (ceria) and the kind and content of the cationic organic polymer particles (B) in the first liquid were changed as shown in Table 3.

Meanwhile, the second liquids were prepared in the same manner as in Example 10 except that the kind and content of the anionic water-soluble compound (C) in the second liquid were changed as shown in Table 3.

Then, aqueous dispersions for chemical mechanical polishing that contained abrasives (9) to (17) were prepared in the same manner as in Example 10 except that the first and second liquids were used in such amounts that the contents of the components (A), (B) and (C) in the concentrate of aqueous dispersion for chemical mechanical polishing became as shown in Table 5.

Chemical mechanical polishing tests were conducted in the same manner as in Example 1 by use of the above prepared aqueous dispersions for chemical mechanical polishing. The results are shown in Table 6.

### Comparative Example 4

A chemical mechanical polishing test was conducted in the same manner as in Comparative Example 1 except that an aqueous dispersion for chemical mechanical polishing prepared by diluting the aqueous dispersion for chemical mechanical polishing prepared in Comparative Example 1 with ion exchange water such that the content of the abrasives (15) became 0.07 wt % was used. The results are shown in Table 6. In the present comparative example, an evaluation of scratches was not made, since it was obvious that the removal rate was so low that the aqueous dispersion was not practicable.

### Comparative Example 5

To ion exchange water charged into a vessel in advance, CERIASOLCESL-40N (average particle diameter: 40 nm, ceria content: 20 wt %) of DAIICHI KIGENSO KAGAKU KOGYO CO., LTD. was added and diluted with ion exchange water such that the content of ceria in a concentrate of aqueous dispersion for chemical mechanical polishing became 5 wt %. To the resulting composition, an aqueous solution containing 10 wt % of ammonium polyacrylate having an Mw of 10,000 was added in such an amount that the content of ammonium polyacrylate in the concentrate of aqueous dispersion for chemical mechanical polishing became 2.0 wt %, and the mixture was agitated for 10 minutes. This was filtered by a polypropylene depth filter having a pore diameter of 5 μm to obtain a concentrate of aqueous dispersion for chemical mechanical polishing that contained 5 wt % of ceria (a).

After this concentrate was diluted with ion exchange water such that the ceria content became 0.5 wt %, a chemical mechanical polishing test was conducted in the same manner as in Example 1. The results are shown in Table 6. In the present comparative example, an evaluation of scratches was not made, since it was obvious that the removal rate was so low that the aqueous dispersion was not practicable.

### Comparative Example 6

Cerium carbonate was heated in air at 800° C. for 4 hours to obtain ceria. This ceria was mixed with ion exchange water and pulverized by means of bead mills using zirconia beads. This was left to stand for 24 hours and classified by isolating an upper portion equivalent to 90 wt % to obtain a ceria water dispersion containing 31.6 wt % of ceria. When the average particle diameter of the obtained ceria was measured by a laser diffraction method, it was 440 nm.

A concentrate of aqueous dispersion for chemical mechanical polishing that contained 5 wt % of ceria (b) was obtained in the same manner as in Comparative Example 1 except that this ceria water dispersion was used in place of CESL-40N.

After this concentrate was diluted with ion exchange water such that the content of the abrasives became a value shown in Table 6, a chemical mechanical polishing test was conducted in the same manner as in Example 1. The results are shown in Table 6.

### Comparative Example 7

The above ceria-(b)-containing concentrate prepared in Comparative Example 2 and the above organic-particles-(a)-containing water dispersion prepared in Synthesis Example 1 were mixed together. After the mixture was diluted with ion exchange water such that the contents of the ceria (b) and the organic particles (a) became values shown in Table 6, a chemical mechanical polishing test was conducted in the same manner as in Example 1. The results are shown in Table 6.

### Comparative Example 8

The above ceria-(b)-containing concentrate prepared in Comparative Example 6 and the above organic-particles-(f)-containing water dispersion prepared in Synthesis Example 6 were mixed together. After the mixture was diluted with ion exchange water such that the contents of the ceria (b) and the organic particles (f) became values shown in Table 6, a chemical mechanical polishing test was conducted in the same manner as in Example 1. The results are shown in Table 6.

TABLE 2

| | First Liquid | | | Second Liquid | |
|---|---|---|---|---|---|
| | | (B) Cationic Organic | | (C) Anionic Water- | |
| | | Polymer Particles | | Soluble Compound | |
| | (A) Ceria Content | | Content | | Content |
| | (wt %) | Kind | (wt %) | Kind | (wt %) |
| Abrasives (1) | 6.25 | Organic Particles (a) | 0.625 | PAAA (1) | 10.0 |
| Abrasives (2) | 6.67 | Organic Particles (b) | 1.33 | PAAA (1) | 10.0 |
| Abrasives (3) | 7.14 | Organic Particles (b) | 2.86 | PAAA (2) | 10.0 |
| Abrasives (4) | 6.25 | Organic Particles (c) | 2.50 | PAAA (1) | 10.0 |
| Abrasives (5) | 6.25 | Organic Particles (d) | 1.25 | PAAA (2) | 10.0 |
| Abrasives (6) | 5.55 | Organic Particles (a) | 4.44 | DBSA | 10.0 |
| Abrasives (7) | 5.55 | Organic Particles (a) | 1.11 | DBSA | 10.0 |

TABLE 3

| | Concentrate of First Liquid | | | Second Liquid | |
|---|---|---|---|---|---|
| | | (B) Cationic Organic | | (C) Anionic Water- | |
| | | Polymer Particles | | Soluble Compound | |
| | (A) Ceria Content | | Content | | Content |
| | (wt %) | Kind | (wt %) | Kind | (wt %) |
| Abrasives (8) | 5.0 | Organic Particles (a) | 0.5 | PAAA (2) | 30.0 |
| Abrasives (9) | 5.0 | Organic Particles (a) | 4.0 | PAAA (1) | 10.0 |
| Abrasives (10) | 5.0 | Organic Particles (a) | 3.0 | PAAA (1) | 10.0 |
| Abrasives (11) | 5.0 | Organic Particles (b) | 1.0 | PAAA (1) | 20.0 |
| Abrasives (12) | 5.0 | Organic Particles (d) | 0.25 | PAAA (2) | 30.0 |
| Abrasives (13) | 5.0 | Organic Particles (c) | 0.5 | DBSA | 10.0 |
| Abrasives (14) | 5.0 | Organic Particles (a) | 1.0 | PAAA (1) | 40.0 |
| Abrasives (15) | 5.0 | Organic Particles (a) | 5.0 | PAAA (2) | 30.0 |
| Abrasives (16) | 5.0 | Organic Particles (c) | 7.0 | PAAA (1) | 20.0 |
| Abrasives (17) | 5.0 | Organic Particles (e) | 0.2 | DBSA | 10.0 |

TABLE 4

| | (B) Cationic Organic | | | (C) Anionic Water- | |
|---|---|---|---|---|---|
| | Polymer Particles | | | Soluble Compound | |
| | (A) Ceria Content | | Content | | Content |
| | (wt %) | Kind | (wt %) | Kind | (wt %) |
| Abrasives (1) | 5.0 | Organic Particles (a) | 0.5 | PAAA (1) | 2.0 |
| Abrasives (2) | 5.0 | Organic Particles (b) | 1.0 | PAAA (1) | 2.5 |
| Abrasives (3) | 5.0 | Organic Particles (b) | 2.0 | PAAA (2) | 3.0 |
| Abrasives (4) | 5.0 | Organic Particles (c) | 2.0 | PAAA (1) | 2.0 |
| Abrasives (5) | 5.0 | Organic Particles (d) | 1.0 | PAAA (2) | 2.0 |
| Abrasives (6) | 5.0 | Organic Particles (a) | 4.0 | DBSA | 1.0 |
| Abrasives (7) | 5.0 | Organic Particles (a) | 1.0 | DBSA | 1.0 |

TABLE 5

| | | (B) Cationic Organic | | (C) Anionic Water- | |
|---|---|---|---|---|---|
| | | Polymer Particles | | Soluble Compound | |
| | (A) Ceria Content | | Content | | Content |
| | (wt %) | Kind | (wt %) | Kind | (wt %) |
| Abrasives (8) | 0.5 | Organic Particles (a) | 0.05 | PAAA (2) | 0.25 |
| Abrasives (9) | 0.5 | Organic Particles (a) | 0.4 | PAAA (1) | 0.025 |
| Abrasives (10) | 0.5 | Organic Particles (a) | 0.3 | PAAA (1) | 0.05 |
| Abrasives (11) | 0.31 | Organic Particles (b) | 0.062 | PAAA (1) | 0.031 |
| Abrasives (12) | 0.5 | Organic Particles (d) | 0.025 | PAAA (2) | 0.6 |
| Abrasives (13) | 0.5 | Organic Particles (c) | 0.5 | DBSA | 0.025 |
| Abrasives (14) | 0.5 | Organic Particles (a) | 0.1 | PAAA (1) | 0.25 |
| Abrasives (15) | 0.5 | Organic Particles (a) | 0.5 | PAAA (2) | 0.7 |
| Abrasives (16) | 0.5 | Organic Particles (c) | 0.7 | PAAA (1) | 0.02 |
| Abrasives (17) | 0.5 | Organic Particles (e) | 0.02 | DBSA | 0.02 |

The abbreviations in Tables 2 to 4 indicate the following.

### (C) Anionic Water-Soluble Compound;

PAAA (1): ammonium polyacrylate, Mw=10,000

PAAA (2): ammonium polyacrylate, Mw=6,000

DBSA: ammonium dodecylbenzene sulfonate

TABLE 6

| | Aqueous Dispersion for Chemical Mechanical | | | | Chemical Mechanical | |
|---|---|---|---|---|---|---|
| | Polishing | | | | Polishing Test | |
| | Abrasives | | Other Additives | | Polishing | |
| | | Content | | Content | Rate | Number of Scratches |
| | Kind | (wt %) | Kind | (wt %) | (nm/min) | (number/wafer) |
| Ex. 1 | Abrasives (1) | 2.0 | — | — | 363 | 15 |
| Ex. 2 | Abrasives (1) | 1.0 | — | — | 321 | 18 |
| Ex. 3 | Abrasives (1) | 0.4 | — | — | 221 | 21 |
| Ex. 4 | Abrasives (2) | 0.6 | — | — | 275 | 16 |
| Ex. 5 | Abrasives (3) | 0.7 | — | — | 283 | 27 |
| Ex. 6 | Abrasives (4) | 0.7 | — | — | 259 | 7 |
| Ex. 7 | Abrasives (5) | 0.6 | — | — | 221 | 31 |
| Ex. 8 | Abrasives (6) | 0.8 | — | — | 243 | 39 |
| Ex. 9 | Abrasives (7) | 1.2 | — | — | 296 | 49 |
| Ex. 10 | Abrasives (8) | 0.8 | — | — | 246 | 13 |
| Ex. 11 | Abrasives (9) | 0.93 | — | — | 219 | 6 |
| Ex. 12 | Abrasives (10) | 0.85 | — | — | 242 | 18 |
| Ex. 13 | Abrasives (11) | 0.40 | — | — | 384 | 11 |
| Ex. 14 | Abrasives (12) | 1.13 | — | — | 237 | 25 |
| Ex. 15 | Abrasives (13) | 1.03 | — | — | 206 | 3 |
| Ex. 16 | Abrasives (14) | 0.85 | — | — | 469 | 9 |
| C. Ex. 1 | Abrasives (15) | 1.70 | — | — | 37 | 5 |
| C. Ex. 2 | Abrasives (16) | 1.22 | — | — | 47 | 3 |
| C. Ex. 3 | Abrasives (17) | 0.54 | — | — | 579 | 435 |
| C. Ex. 4 | Abrasives (15) | 0.07 | — | — | 8 | — |
| C. Ex. 5 | Ceria (a) | 0.5 | PAAA | 0.2 | 6 | — |
| C. Ex. 6 | Ceria (b) | 0.5 | PAAA | 0.2 | 560 | 476 |
| C. Ex. 7 | Ceria (b)/Organic Particles (a) | 0.5/0.1 | — | — | 420 | 290 |
| C. Ex. 8 | Ceria (b)/Organic Particles (f) | 0.5/0.2 | — | — | 395 | 386 |

Ex.: Example

### Example 17

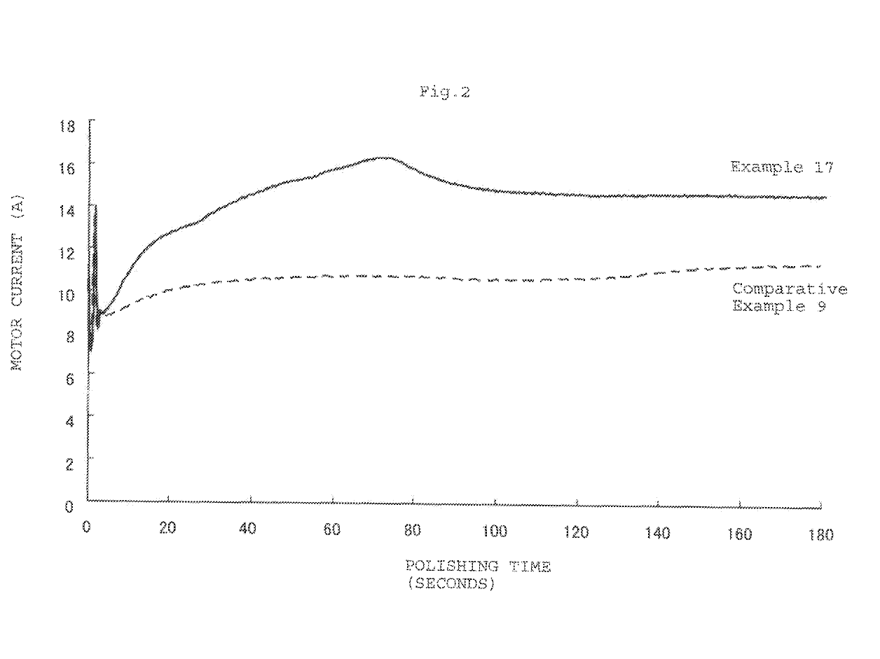

A chemical mechanical polishing test was conducted for 3 minutes in the same manner as in Example 1 except that the aqueous dispersion for chemical mechanical polishing prepared in Example 4 (diluted one) was used and 864CMP (test wafer of Advanced Materials Technology Inc. It has a cross section structure wherein depth of a groove 2 from the top surface of silicon nitride 4 to the bottom of the groove 2 is about 5,000 Å, the thickness of silicon oxide layer 3 is about 100 Å and the thickness of silicon nitride layer 4 is about 1,500 Å.) was used as an object to be polished, in FIG. 1. A motor current for rotating a platen in the polishing test is shown in FIG. 2.

According to changes with time in the current value in FIG. 2, after getting out of the unstable state in the initial stage of polishing, the current was increasing, and after it reached the maximum value around 70 seconds from the start of polishing and then decreased, an inflection point is seen at about 80 seconds from the start of polishing.

To confirm that this point was the end point of polishing, polishing was conducted under the same polishing conditions by use of an object to be polished of the same type as described above while a current value of a motor that rotates a platen of a chemical mechanical polishing apparatus was tracked, and the polishing was ended at a point where the current value turned from increasing to decreasing and an inflection point was detected. As a result of analyzing the polished surface by an optical interferometrical film thickness meter “NanoSpec 6100” (product of Nanometrics Japan Incorporated), the thickness of the silicon oxide layer on the silicon nitride layer in each pattern having a pattern density of 30 to 90% and a pitch of 100 μm was 0 Å. Further, since a decrease in the thickness of the silicon nitride layer by polishing was not larger than 50A and the silicon nitride layer was hardly polished in any of the patterns having a pattern density of 30 to 90% and a pitch of 100 μm, it was found that the above point where the inflection point appeared could be used as the end point of polishing.

### Comparative Example 9

A 3-minute chemical mechanical polishing test was conducted in the same manner as in Example 17 except that the aqueous dispersion for chemical mechanical polishing prepared in Comparative Example 6 (diluted one) was used as the aqueous dispersion for chemical mechanical polishing. A torque current in the polishing test is shown in FIG. 2.

It is assumed from the polishing rate evaluated in Comparative Example 6 that the end point is reached in a shorter time than the case of Example 17. However, it was found that the current value of Comparative Example 9 showed no tendency around an assumed end point and the end point could not be detected by tracking of the current value.

### Example 18

The present example was conducted to verify that in the abrasives of the present invention, the inorganic particles comprising ceria (A) and the cationic organic polymer particles (B) are aggregated via the anionic water-soluble compound (C).

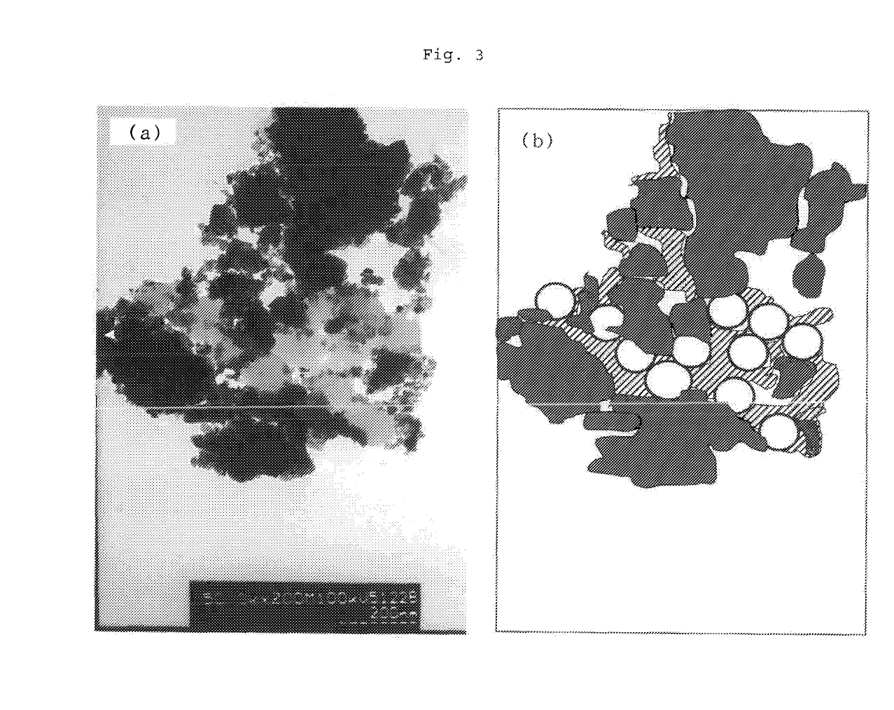

After the aqueous dispersion for chemical mechanical polishing prepared in Example 1 was further diluted with ion exchange water, applied on a collodion film and dried, a transmission electron microscope (TEM) photograph was taken. It is understood from this photograph that in the present abrasives, ceria and the organic particles (a) are aggregated via ammonium polyacrylate. This electron microscope photograph is shown in FIG. 3. FIG. 3(a) is a TEM image, and FIG. 3(b) is a reference diagram for understanding the TEM image. In FIG. 3(a), ceria is seen as the blackest (corresponding to blacked-out portions in (b)), the organic particles (a) are seen as translucent spheres (corresponding to white outlined circles in (b)), and ameba-like translucent portions surrounding the ceria and the organic particles are ammonium polyacrylate (corresponding to shaded portions in (b)).

1. An aqueous dispersion for chemical mechanical polishing that comprises abrasives comprising:
(A) 100 parts by weight of inorganic particles comprising ceria,
(B) 5 to 100 parts by weight of cationic organic polymer particles, and
(C) 5 to 120 parts by weight of anionic water-soluble compound.

2. The aqueous dispersion of claim 1, wherein based on 100 parts by weight of the inorganic particles comprising ceria (A), the amount of the cationic organic polymer particles (B) is 10 to 80 parts by weight and the amount of the anionic water-soluble compound (C) is 10 to 50 parts by weight.

3. The aqueous dispersion of claim 1 or 2, wherein the content of the abrasives is 0.1 to 2.0 wt %.

4. The aqueous dispersion of claim 1 or 2, wherein the content of the abrasives is 0.1 to 0.8 wt %.

5. The aqueous dispersion of claim 1 or 2, wherein in the abrasives, the inorganic particles comprising ceria (A) and the cationic organic polymer particles (B) are aggregated via the anionic water-soluble compound (C).

6. A method for producing the aqueous dispersion for chemical mechanical polishing of claim 1, comprising a step of adding a second liquid comprising (C) 5 to 30 wt % of anionic water-soluble compound to a first liquid comprising (A) 0.1 to 10 wt % of inorganic particles comprising ceria and (B) 5 to 100 parts by weight of cationic organic polymer particles based on 100 parts by weight of the inorganic particles (A).

7. A set for producing the aqueous dispersion for chemical mechanical polishing of claim 1, comprising:
a first liquid comprising (A) 100 parts by weight of inorganic particles comprising ceria and (B) 5 to 100 parts by weight of cationic organic polymer particles, and
a second liquid comprising (C) an anionic water-soluble compound.

8. A chemical mechanical polishing method comprising polishing a surface to be polished of an object to be polished by use of the aqueous dispersion for chemical mechanical polishing of claim 1.

9. The method of claim 8, wherein at least a part of the surface to be polished is an insulation film.

10. The method of claim 8 or 9, which tracks a current value of a motor that rotates a platen of a chemical mechanical polishing apparatus and determines a point at which the current value shows an inflection point after turning from increasing to decreasing in a graph illustrating a change in the current value with time, as the endpoint of chemical mechanical polishing.
